(19) United States
(12) Patent Application Publication
(10) Pub. No.: US 2009/0201015 A1
(43) Pub. Date: Aug. 13, 2009

(54) METHOD AND DEVICE FOR DETECTING FERROELECTRIC POLARIZATION

(75) Inventors: Donald Edward Adams, Pleasanton, CA (US); Tsung-Kuan Allen Chou, San Jose, CA (US); Robert N. Stark, Saratoga, CA (US)

Correspondence Address: FLIESLER MEYER LLP, 650 CALIFORNIA STREET, 14TH FLOOR, SAN FRANCISCO, CA, 94108, US

(73) Assignee: NANOCHIP, INC., Fremont, CA (US)

(21) Appl. No.: 12/030,101

(22) Filed: Feb. 12, 2008

(51) Int. Cl. G01R 33/12

(52) U.S. Cl. 324/210

(57) ABSTRACT

An information storage device comprises a ferroelectric media and a cantilever including a tip extending from the cantilever toward the ferroelectric media, and a capacitive sensor formed over the cantilever. The tip applies a probe voltage to the ferroelectric media and the capacitive sensor vibrates according to a response of the ferroelectric media to the probe voltage. Circuitry determines a polarization of the ferroelectric media based on the vibration of the capacitive sensor.

### BACKGROUND

Software developers continue to develop steadily more data intensive products, such as ever-more sophisticated, and graphic intensive applications and operating systems. As a result, higher capacity memory, both volatile and non-volatile, has been in persistent demand. Added to this demand is the need for capacity for storing data and media files, and the confluence of personal computing and consumer electronics in the form of portable media players (PMPs), personal digital assistants (PDAs), sophisticated mobile phones, and laptop computers, all of which place a premium on compactness and reliability.

Nearly every personal computer and server in use today contains one or more hard disk drives (HDD) for permanently storing frequently accessed data. Every mainframe and supercomputer is connected to hundreds of HDDs. Consumer electronic goods ranging from camcorders to digital data recorders use HDDs. While HDDs store large amounts of data, HDDs consume a great deal of power, require long access times, and require “spin-up” time on power-up. Further, HDD technology based on magnetic recording technology is approaching a physical limitation due to super paramagnetic phenomenon. Data storage devices based on scanning probe microscopy (SPM) techniques have been studied as future ultra-high density (>1 Tbit/in2) systems. There is a need for techniques and structures to read and write to a ferroelectric media that facilitate desirable data bit transfer rates and areal densities.

### BRIEF DESCRIPTION OF THE DRAWINGS

Further details of the present invention are explained with the help of the attached drawings in which:

FIG. 1 is a cross-sectional side view of an information storage device including a plurality of tips extending from corresponding cantilevers toward a movable media.

FIG. 2 is a circuit schematic of an embodiment of a capacitive sensor detector for measuring polarization of a ferroelectric media in accordance with the present invention.

FIGS. 3A-3E are plots of signal inputs and resulting outputs produced by a software modeled circuit resembling the circuit of FIG. 2.

FIG. 4A is a plan view of an embodiment of a cantilever and B-plate in accordance with the present invention illustrating trace layout of conductive components.

FIG. 4B is a side view of the cantilever and B-plate of FIG. 4A, the side view illustrating bending of the cantilever and B-plate as a result of vibration.

FIG. 5A is a schematic representation of the cantilever and B-plate of FIG. 4A illustrating sources of parasitic capacitance.

FIG. 5B is a schematic cut-away view of the cantilever and B-plate of FIG. 4A along the axis of the cantilever and illustrating parasitic capacitance between an A-lead associated with the tip and the B-plate.

FIG. 6A is a plan view of an alternative embodiment of a cantilever and B-plate in accordance with the present invention.

FIG. 6B is a partial cross-sectional view of the cantilever and B-plate of FIG. 6A including a portion of a tip die with which the cantilever is connected.

FIG. 7A is a plan view of a still further embodiment of a cantilever and B-plate in accordance with the present invention.

FIG. 7B is a cross-sectional side view of the cantilever and B-plate of FIG. 7A taken through portions of the B-plate that behave as sensor electrodes.

FIG. 7C is a cross-sectional side view of the cantilever and B-plate of FIG. 7A taken through a supporting portion of the cantilever.

FIGS. 8A-8D illustrate maximum displacement during vibration of the cross-sectional portions of FIGS. 7B and 7C at a frequency matched to a resonant frequency of the cantilever.

FIGS. 9A-9D illustrate maximum displacement during vibration of the cross-sectional portions of FIGS. 7B and 7C at a frequency matched to a resonant frequency of the B-plate.

FIGS. 10A-10D illustrate maximum displacement during vibration of the cross-sectional portions of FIGS. 7B and 7C at a frequency matched to a resonant frequency of the cantilever and B-plate.

FIG. 11A is a plan view of a still further embodiment of a cantilever and B-plate in accordance with the present invention.

FIG. 11B is a cross-sectional side view of the cantilever and B-plate of FIG. 11A taken through portions of the B-plate that behave as sensor electrodes having different geometries.

FIG. 11C is a simplified plot of resonant frequency along the sensor electrodes of the cantilever and B-plate of FIG. 11A.

### DETAILED DESCRIPTION

Common reference numerals are used throughout the drawings and detailed description to indicate like elements; therefore, reference numerals used in a drawing may or may not be referenced in the detailed description specific to such drawing if the associated element is described elsewhere.

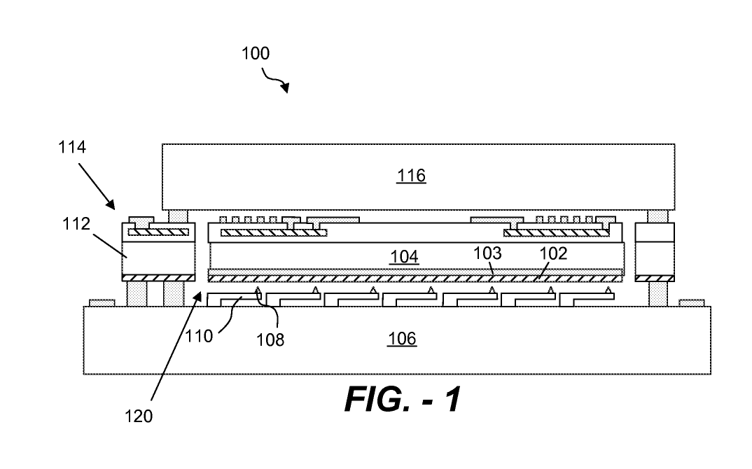

FIG. 1 is a simplified cross-sectional diagram of a system for storing information 100 (also referred to herein as a memory device) with which embodiments of systems and methods for determining ferroelectric polarization in a ferroelectric media in accordance with the present invention can be used. Memory devices enabling potentially higher density storage relative to current ferromagnetic and solid state storage technology can include nanometer-scale heads such as contact probe tips, non-contact probe tips, and the like capable of one or both of reading and writing to a media. Memory devices for high density storage can include seek-and-scan probe (SSP) memory devices comprising cantilevers from which probe tips extend for communicating with a media using scanning-probe techniques. The cantilevers and probe tips can be implemented in a micro-electromechanical systems (MEMS) device with a plurality of read-write channels working in parallel. Probe tips are hereinafter referred to as tips and can comprise structures that communicate with a media in one or more of contact, near contact, and non-contact mode. A tip need not be a protruding structure. For example, in some embodiments, a tip can comprise a cantilever or a portion of the cantilever.

The memory device 100 of FIG. 1 comprises a tip die 106 arranged substantially parallel to a media 102. Cantilevers 110 extend from the tip die 106, and tips 108 extend from respective cantilevers 110 toward the surface of the media 102. A recording layer of the media 102 can comprise a ferroelectric material. The media 102 indicia is associated with a movable media platform 104. The movable media platform 104 is suspended and movable within a media frame 112 of a media die 114, for example by flexure structures (not shown). The media platform 104 can be urged within the frame 112 by way of thermal actuators, piezoelectric actuators, voice coil motors 132, etc. The media die 114 can be bonded with the tip die 106 and a cap die 116 can be bonded with the media die 114 to seal the media platform 104 within a cavity 120. Optionally, nitrogen or some other passivation gas can be introduced and sealed in the cavity 120. In alternative embodiments, memory devices can be employed wherein a tip platform is urged relative to the media, or alternative wherein both the tip platform and media can be urged.

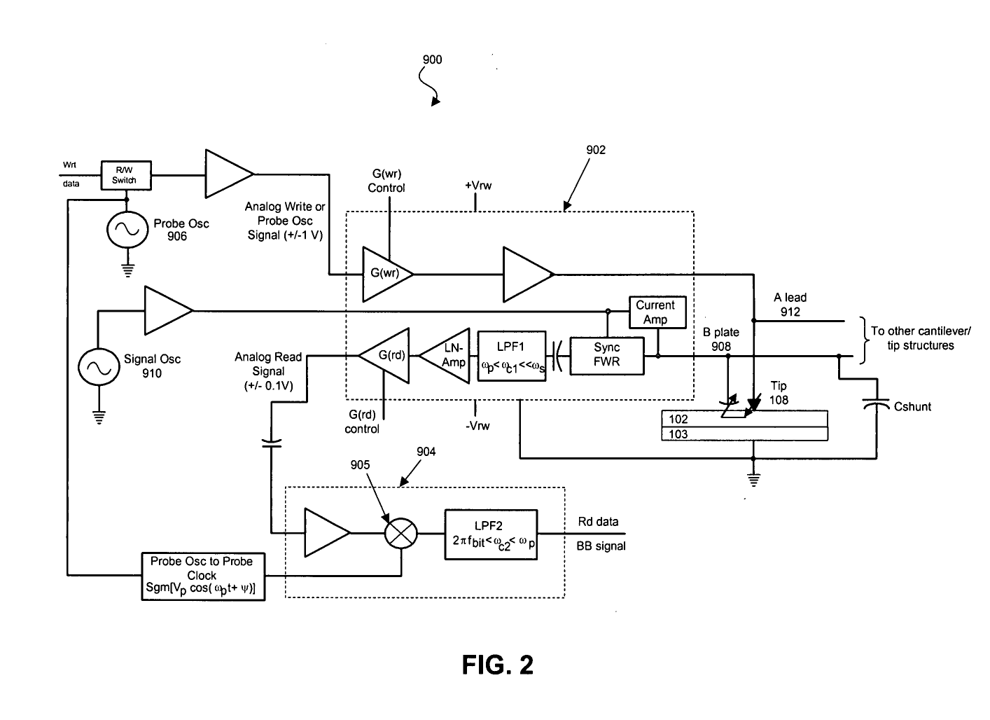

FIG. 2 is a circuit schematic of an embodiment of a capacitive sensor detector and write circuit 900 in accordance with the present invention for use with a memory device such as shown in FIG. 1. The capacitive sensor detector can be fabricated using complementary metal-oxide semiconductor (CMOS) processing and can be applied to determine a polarization of a ferroelectric domain over which a tip 108 is arranged. A probe field, Vₚ, is generated by a probe oscillator 906 and varies at a frequency ωₚ. The probe field is applied by way of the tip 108 through a ferroelectric media 102 or media stack. The ferroelectric media 102 or media stack can comprise, for example, one or more layers of patterned and/or unpatterned strontium titanate (STO), strontium ruthenate (SRO), and/or lead zirconate titanate (PZT). The ferroelectric media 102 expands and contracts some small amount in response to the probe field, for example a fraction of an angstrom. The tip 108 vibrates in response to the expansion and contraction of the ferroelectric media 102. A structure (referred to herein as one or both of a sensing electrode and a B-plate) 908 formed along the cantilever acts with a bottom electrode 103 as a capacitive sensor. The B-plate 908 vibrates in response to vibration of the tip 108 and vibration of the B-plate 908 modulates the B-plate capacitance. The modulation of the B-plate capacitance has a characteristic phase associated with the polarization of the ferroelectric media.

An oscillating current generated by a signal oscillator 910 and having a frequency ωₛ develops a proportional voltage (also referred to herein as a signal field) that can act as an amplitude modulated carrier. A modulating signal can be applied to and extracted from the carrier by passing the carrier through a write/read amplifier 902. In the embodiment shown, the write/read amplifier 902 includes an amplitude modulation (AM) demodulator. The AM demodulator includes a current amplifier, a synchronous full-wave rectifier (Sync FWR) and a low pass filter (LPF1) (where ω_{c1} is the corner frequency to select the lower band of the output of the synchronous full-wave rectifier). The signal field is passed to the current amplifier and modulated by the vibrating B-plate capacitance (the modulating signal, having a frequency of the recorded data, ˜2 πf_{bit} where f_{bit} corresponds to the highest rate of the channel). The amplitude modulated carrier modulated in this way is referred to hereinafter as a B-plate signal. The modulating signal is extracted from the B-plate signal and observed. The extracted signal can be amplified by a low-noise amplifier (LN-Amp). The AM demodulator output (i.e., the read signal) is then passed to a phase detector 904. A phase of the capacitance and hence that of the modulated signal follows the polarization of the ferroelectric media 102 and is extracted with the phase detector 904. A signal is generated by the probe oscillator 906 and passed to a probe oscillator-to-probe clock block (Probe Osc to Probe Clock) to produce a limited and phase delayed version of the probe oscillator signal (i.e., a probe clock) for coherent detection of phase. In the embodiment shown, the phase detector 904 output can be derived as the product of the AM demodulator output and the probe clock through a low pass filter (LPF2) (where ω_{c2} is the corner frequency to select the lower band of the output of a mixer 905) as in any standard coherent phase detector. In this manner the recorded information can be reproduced. In other embodiments, the carrier signal and modulating signal can be separated and amplified using other arrangements of circuit components. One of ordinary skill in the art, in light of the teachings enclosed herein, will appreciate the myriad different circuit designs for extracting the modulating signal. The present invention is not intended to be limited to those circuits presented herein.

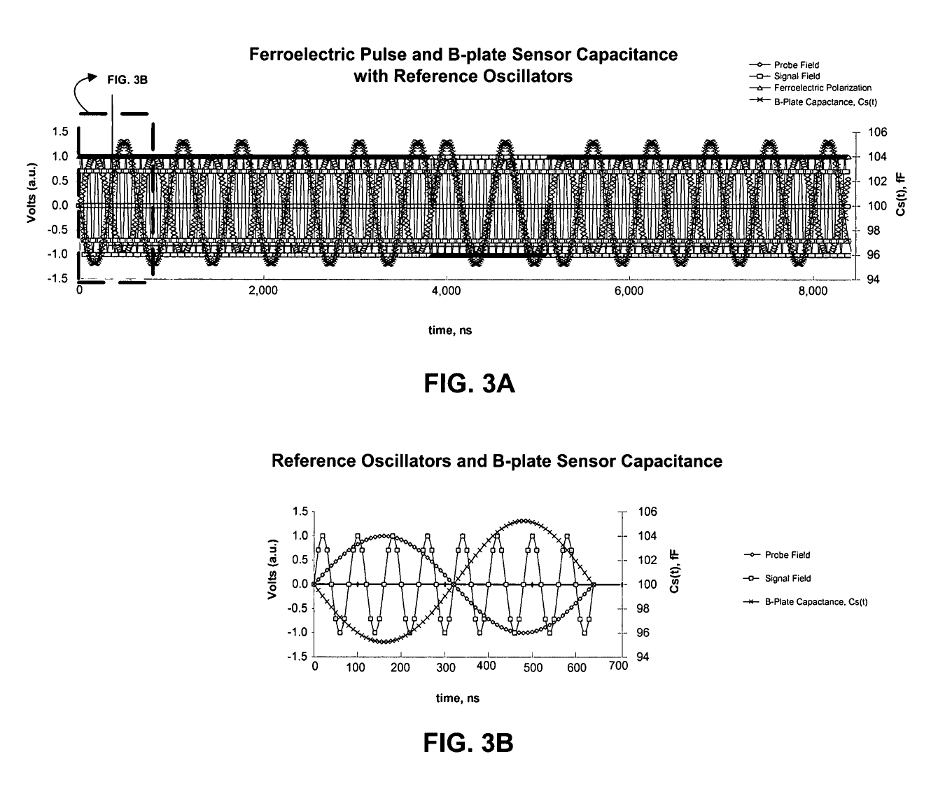

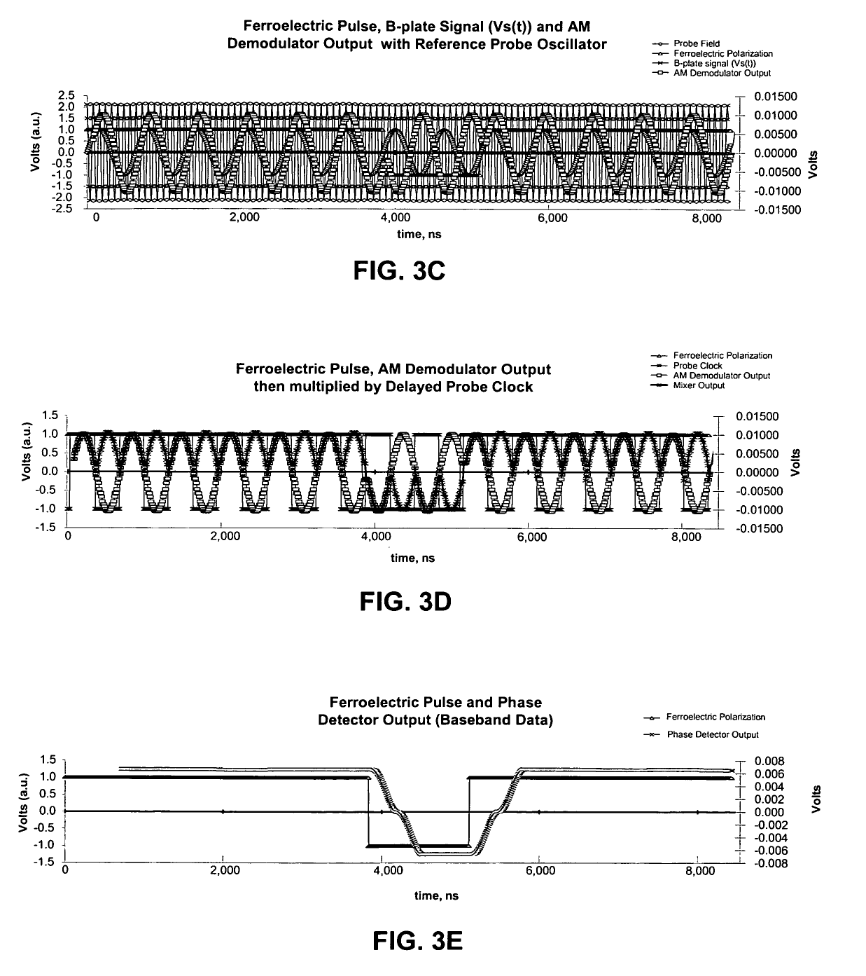

An example of output from a circuit modeled using computer software is illustrated in FIGS. 3A-3E. The output plots illustrate how the circuit is expected to work with a signal from an embodiment of a B-plate acting as a capacitive sensor in accordance with the present invention. Referring to FIG. 3A, a ferroelectric media is modeled having a bit change roughly at a mid-point of a scanned area (illustrated by a step change of the triangular data points from 1 V to −1 V). As can be seen more clearly in FIG. 3B, a probe field (Vₚ, —represented by diamond data points) is generated by a probe oscillator and varies at a frequency of 1.5 MHz. A signal field is generated by a signal oscillator and varies at a frequency of 12 MHz. A predicted B-plate capacitance varies sinusoidal and generally mirrors the probe field at 1 V of ferroelectric pulse polarization, but shifts phase at −1 V of polarization, approximately mapping the probe field. Referring to FIG. 3C, the probe field is plotted against the ferroelectric polarization and the B-plate signal (Vs(t)—represented by cross data points) resulting from modulation of the signal field. The probe field is shown having two cycles per bit cell. In preferred embodiments, the probe field should have at least one cycle per bit cell to permit measurement of phase as affected by the polarization of the ferroelectric media. Further, predicted AM demodulator output is plotted, and phase shifts are shown occurring at pulse polarization transitions (represented by square data points). Referring to FIG. 3D, probe clock (represented by asterisk data points connected by a thin line) and mixer (905, as shown in the circuit of FIG. 2) output (represented by asterisk data points connected by a thick line) are plotted against the AM demodulator output and the ferroelectric polarization. Finally, the phase detector output (represented by shaded cross data points) is plotted against ferroelectric pulse polarization in FIG. 3E, illustrating the predicted read signal from a circuit modeled to resemble the circuit of FIG. 2.

The circuit schematic further illustrates a write circuit path. The tip can be arranged in contact with the ferroelectric media and a field applied to the tip to polarize a domain within the ferroelectric media. The field applied to the ferroelectric media by the write circuit path is generally larger than a time-bearing field applied by the probe oscillator when a read circuit path. The write circuit and read circuit paths are selectably associated with the tip by way of a read/write switch.

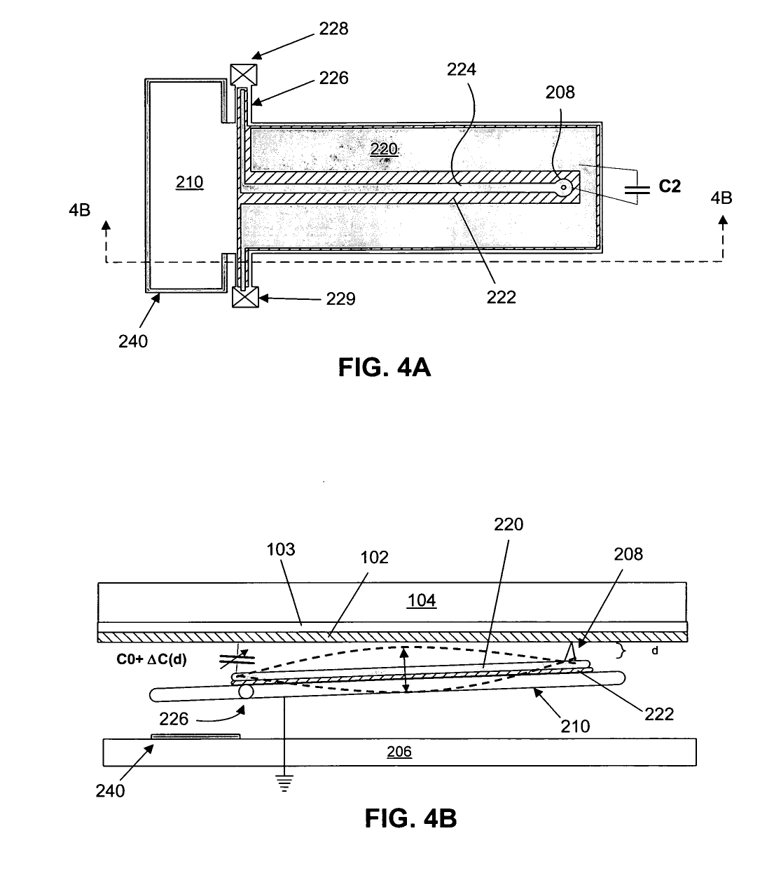

Referring to FIGS. 4A and 4B, an embodiment of a tip 208 and cantilever 210 including a B-plate 220 for communicating a modulating signal in accordance with the present invention is shown. The cantilever 210 is connected and electrically grounded through a tip die 206 by way of a torsion beam 226 connected at both ends to beam anchors 228, 229. The cantilever 210 is rotated about the torsion beam 226 when a voltage is applied to an actuation electrode 240 causing electrostatic force to attract the cantilever 210 to the actuation electrode 240. As the electrode 240 attracts the proximal end of the cantilever 210, the cantilever 210 pivots about the torsion beam 226 and urges the tip 208 toward the ferroelectric media 102. A cantilever pivotable about a torsion beam (also referred to herein as a teeter-totter structure) can allow a tip to be selectively placed in contact or near-contact with a surface of a ferroelectric media. Such an arrangement can reduce wear on the tip and/or associate selected tip(s) with read/write circuitry, thereby reducing circuitry by way of shared traces and circuit components. However, in other embodiments, the cantilever may or may not be actuatable. For example, the tip can be maintained in contact with a media with a cantilever applying a spring force urging the tip toward the media. Further, in some embodiments the cantilever can be actuated by a structure other than that shown in FIG. 4A. For example, in other embodiments the cantilever can be actuated by a thermal actuator comprising a thermal bimorph structure disposed along the cantilever.

The B-plate 220 can be formed of a conductive material (e.g., materials including but not limited to platinum, gold, aluminum, and metal alloys such as platinum-iridium) and as shown is disposed along a substantial portion of the areal surface of the cantilever 210, extending along both sides of the tip 208. The B-plate 220 preferably extends along the cantilever approximately from at least the tip 208 to a torsion beam 226 connecting the cantilever 210 to an anchor 228. However, the B-plate 220 need only have a geometry capable of generating a modulating signal with a signal-to-noise ratio (SNR) of the modulating signal to parasitic capacitances (which capacitances vary at least partially with the geometry of the B-plate, as described below) sufficiently large such that a meaningful modulating signal can be extracted from a carrier. The tip 208 extends from a distal end of the cantilever 210 and is electrically connected with a read/write circuit by a trace (also referred to herein as an A-lead) 224. As shown, the A-lead 224 extends along the cantilever 210 and electrically connects with routing circuitry 230 formed on the tip die 206. The B-plate 220 is also electrically connected with read circuitry by a trace extending from the B-plate 220. The trace layout shown is merely exemplary, and in other embodiments a different routing path can be used. The B-plate 220 and A-lead 224 can be isolated from the body of the cantilever by a dielectric layer 222, for example comprising silicon dioxide (SiO2) or silicon carbide (SiC).

Referring again to FIGS. 4A and 4B, the tip 208 is shown placed in contact and/or electrical communication with the ferroelectric media 102. (It should be noted that illustrated elements match previously described elements where reference numerals are common.) A capacitance, Co, exists between the B-plate 220 and the bottom electrode 103. When a read circuit of the structure is active, the tip 208 and media 102 can be urged relative to one another as the tip 208 communicates a probe field to the ferroelectric media 102. The probe field can have a frequency that approximately matches a specific cantilever resonant mode. As mentioned above, the tip 208 vibrates in response to a ferroelectric field of a domain within the media 102, causing the B-plate 220 to vibrate along the B-plate's length, bowing toward and away from the ferroelectric media 102 (as shown by the phantom lines of FIG. 4B). As the B-plate 220 vibrates, the B-plate capacitance, Co, varies. The variation of the B-plate capacitance is referred to herein as a modulating capacitance, ΔC, which modulating capacitance varies as a function of the cantilever vibration amplitude and the air gap, d, between the B-plate 220 and the bottom electrode 103. A small displacement at the tip may induce larger cantilever (and B-plate) displacement (>1 nm) to enhance modulated capacitance, ΔC.

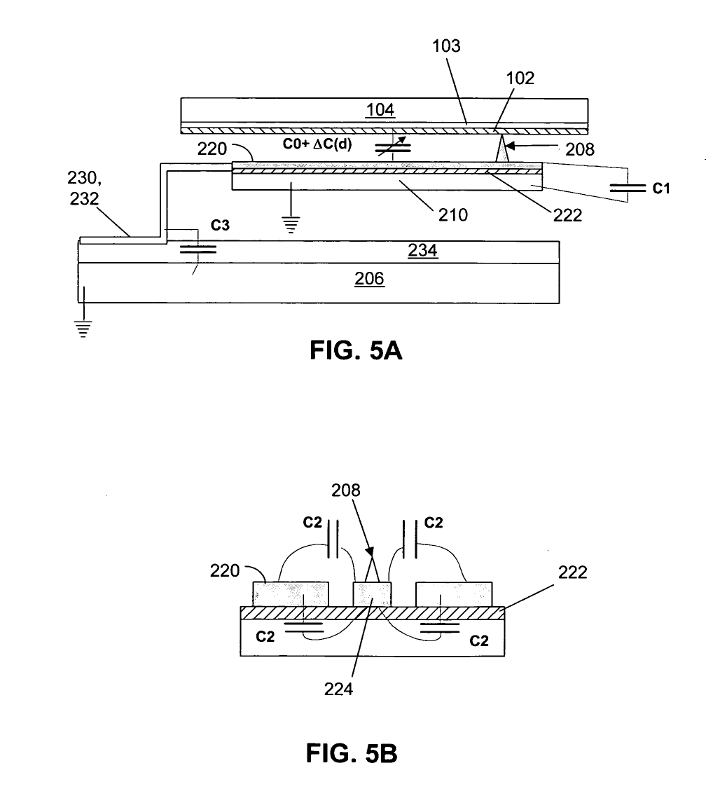

FIG. 5A is a simplified representation of the structure of FIG. 4A including the cantilever 210 and tip 208. The representation shows a portion of the parasitic capacitances associated with the structure, including the modulated capacitance, Co+ΔC, between the B-plate 220 and the bottom electrode 103, common mode capacitance, C1, between the cantilever 210 and the B-plate 220 and trace capacitance, C3, associated with the traces and routing circuitry 230,232 (shown schematically disposed within an interlayer dielectric 234). Further, FIGS. 4A and 5B include schematic representation of a coupling capacitance, C2, between the B-plate 220 and the A-lead 224. The capacitance communicated to the sensing circuit is a sum of all capacitances, Co+C1+C2+C3+ΔC. The ferroelectric media 102 and tip 208 can be urged relative to one another so that the B-plate 220 and cantilever 210 vibrate near a resonant frequency of the cantilever 210 to maximize displacement of the B-plate 220 and cantilever 210. Maximizing displacement of the B-plate 220 can maximize ΔC, increasing SNR. Further, applying a probe field having a frequency at a resonant frequency of the cantilever can provide benefit from mechanical gain related to resonance, enabling use of a smaller voltage for the probe signal. Reducing the probe signal may reduce a risk of disturbing polarization of the ferroelectric media during reading.

Although vibrating at resonance frequency maximizes displacement of the B-plate, the modulating capacitance, ΔC, may be undesirably small relative to a sum of a capacitance of the B-plate, Co, and parasitic capacitances, C1, C2, and C3 (shown in FIGS. 5A and 5B, and noted in total as shunt capacitance, Cshunt, in the circuit of FIG. 2). It may be desirable to reduce a gap between the B-plate and bottom electrode to increase the modulation of the modulated capacitance; however, the gap is controlled by the height of the tip 208 which may extend to one micron due to fabrication limitation. Alternatively, it may be desirable to increase a surface area of the B-plate and/or reduce parasitic capacitance. Routing trace capacitance, C3, can be reduced by including an on-chip integrated sense circuit associated with the cantilever structure. The B-plate couples with the A-lead through the conductive cantilever body and the coupling capacitance is determined by the narrower trace. The coupling capacitance, C2, can be reduced by minimizing a trace width of the A-lead based on the requirement of the sense circuit.

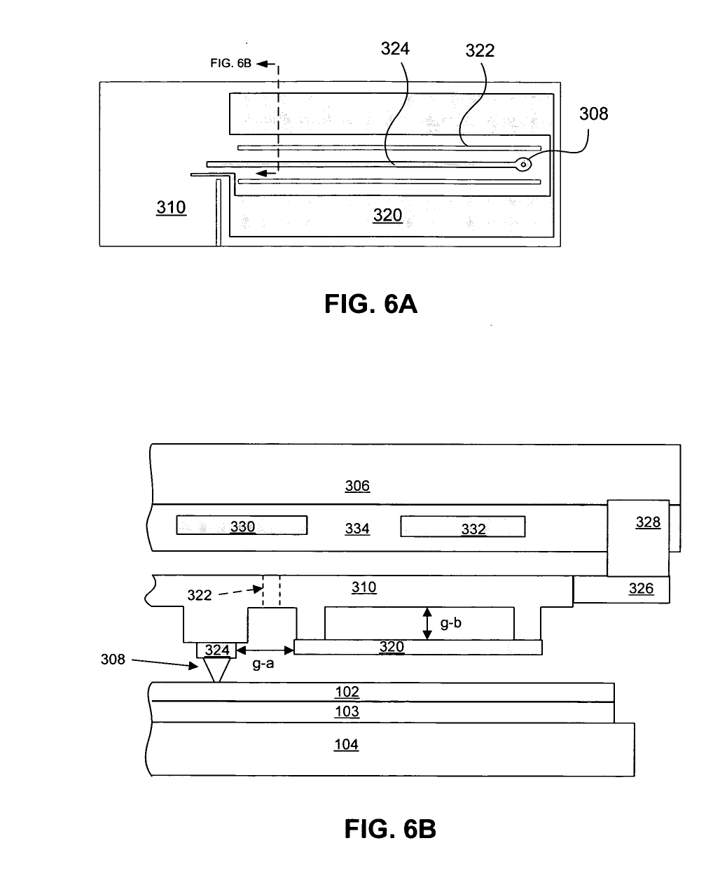

The common mode capacitance, C1, is generated at least partially from the B-plate contacting the grounded cantilever body with a thin dielectric insulator in between and is dependant on the B-plate planar dimension and the thickness of the dielectric. The common mode capacitance is estimated to be roughly 20 times larger than the B-plate capacitance, Co, and can overwhelm the modulating capacitance, ΔC. Referring to FIGS. 6A and 6B, an alternative embodiment of a cantilever 310 and B-plate 320 is shown for use with embodiments of phase detectors and methods of measuring ferroelectric polarization in accordance with the present invention. FIG. 6A is a plan view of the cantilever 310 and B-plate 320 resembling the structure of FIG. 4A. The cantilever 310 further includes tuning slots 322 which can have a geometry that is optionally modifiable during fabrication to adjust frequency and amplitude of the B-plate 320 when vibrating. Frequency and amplitude of the B-plate is defined by geometry. The tuning slots can be varied in size by varying a fabrication step for forming the tuning slots. For example, the geometry of the tuning slot can be increased in size by increasing an etch time, and/or modifying the anisotropic/isotropic behavior of the etch process, or alternatively by adjusting the photolithography process. Tuning slots 322 provide a controllably modifyable structure to correct for variations in other fabrication steps.

FIG. 6B is a partial cross-sectional view of the cantilever and B-plate of FIG. 6A illustrating one structure in accordance with the present invention for reducing common mode capacitance between the B-plate 320 and the cantilever body 310. As can be seen, the B-plate 320 is connected to the cantilever 310 along a periphery by support elements of the cantilever 310. As a result substantial portion of the B-plate 320 is separated from the cantilever 310 by an air gap, g-b. Further, an air gap, g-a, is formed between the B-plate 320 and the A-lead 324 along which the probe signal is communicated to the tip 308. Because air has a much lower dielectric constant than the cantilever body (for example, where the cantilever body is formed from silicon germanium (SiGe)), the common mode capacitance is reduced. It is noted that the coupling capacitance between the A-lead and the B-plate, C2, is also reduced. The cantilever 310 is pivotably connected with a tip die 306 by a torsion beam 326 arranged between anchors 328. Circuitry 330 for communicating with the tip 308 and circuitry 332 for communicating with the B-plate 332 is formed over the tip die 306 within an interlayer dielectric 334.

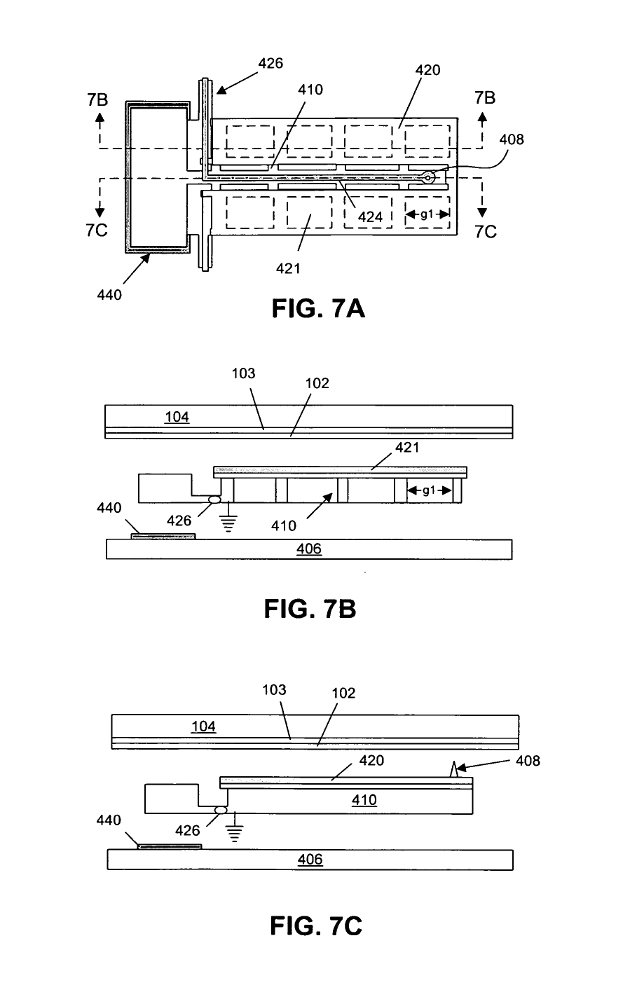

Referring to FIGS. 7-10, an alternative embodiment of a cantilever 410 and B-plate structure 420 is shown for use with embodiments of phase detectors and methods of measuring ferroelectric polarization in accordance with the present invention. As above, the cantilever 410 is connected with the tip die by a torsion beam 426 and pivoted about the torsion beam 426 by application of electrostatic force by the actuation electrode 440 formed on the tip die 406. The cantilever 410 resembles the cantilever of FIG. 6A and includes a frame-like structure with most of the contact area and volume removed. One or more B-plate membranes 420 are connected with the cantilever 410 with full or partial anchor support at peripheries by the cantilever frame. Portions of the B-plate 420 extend over air gaps, g1, in the cantilever frame of substantially the same dimensions and can be considered as discrete suspended electrodes 421. A tip 408 extends from a distal end of the cantilever 410 and is electrically connected with a read/write circuit by an A-lead 424.

As discussed below, if the probe field has a frequency matched to a resonant frequency of the B-plate 420, the suspended electrodes can vibrate independently. The cantilever frame and suspended electrode shapes can vary depending on the desired resonant modes. Such variation can provide a similar tailoring option as the tuning slots 322 of FIG. 4A. The B-plate 420 is electrically isolated from the cantilever 410 with insulator dielectric. As above, the B-plate 420 has less parasitic capacitance with the cantilever 410 compared to a solid cantilever structure. The dominant common mode capacitance, C1, can be minimized by reducing significant overlap area to the grounded cantilever. The B-plate 420 can have a maximized planar area for largest capacitance modulation area. As above, coupling capacitance between the A-lead and B-plate, C2, can also be reduced.

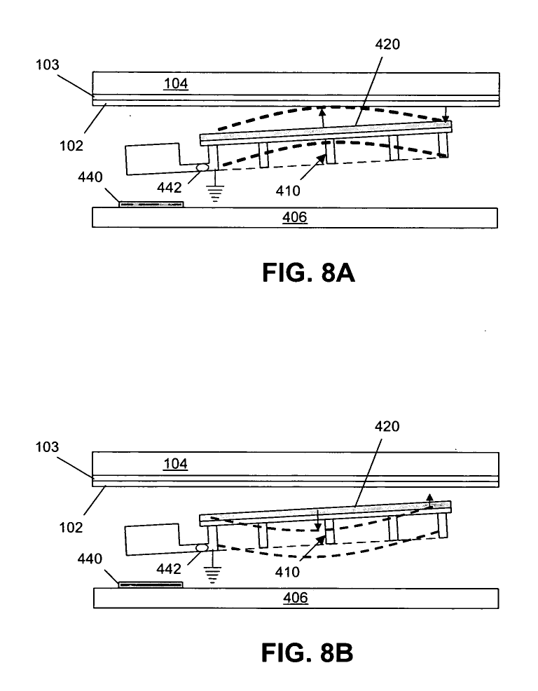

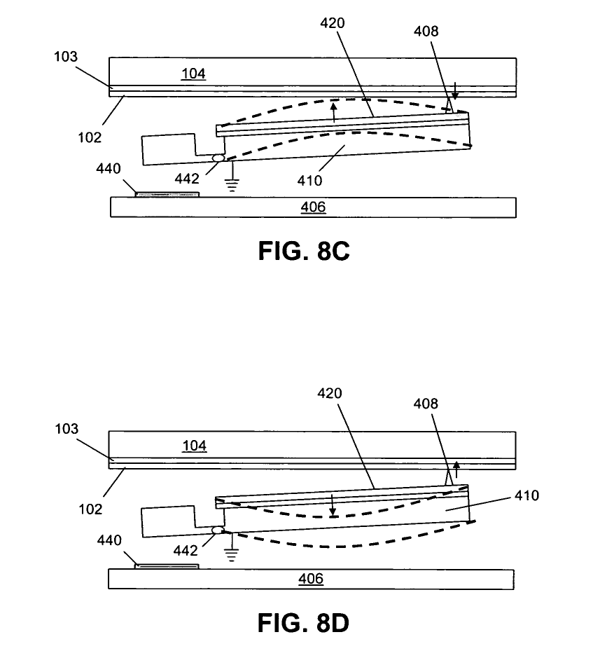

FIGS. 8A-8D illustrate a read mode of the structure of FIGS. 7A-7C. An oscillating potential is generated by the probe oscillator and applied to the tip 408 to cause structure vibration. As described above, expansion and contraction of the ferroelectric media 102 causes the tip 408 to vibrate at the frequency of the oscillating current, which in turn causes the cantilever 410 and/or B-plate 420 to vibrate at the frequency of the oscillating current. When the frequency of the oscillating current is tuned to the cantilever's resonant mode shape (as shown by the phantom lines), the vibration amplitude of the cantilever 410 is maximum. An expected resonance frequency is >1 MHz. The B-plate 420 is anchored to the cantilever frame and can follow the same mode shape of the cantilever 410. FIGS. 8A and 8B illustrate the resonant mode shapes for the cross-sectional views of FIG. 7B. FIGS. 8C and 8D illustrate the resonant mode shapes for the cross-sectional views of FIG. 7C.

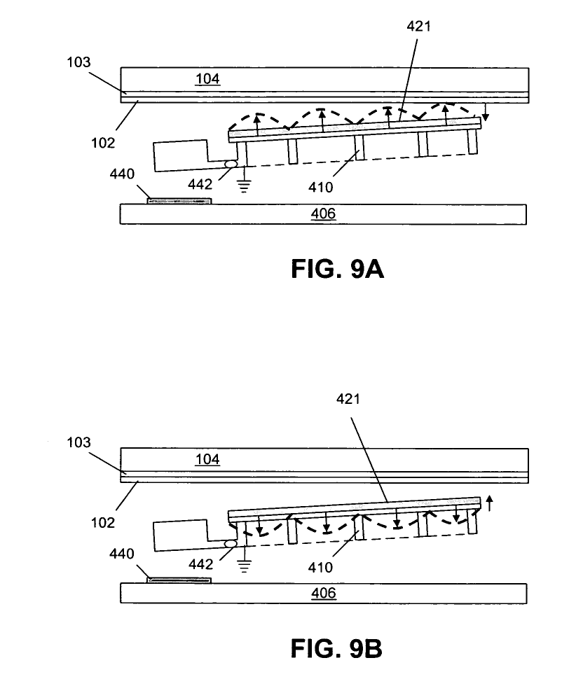

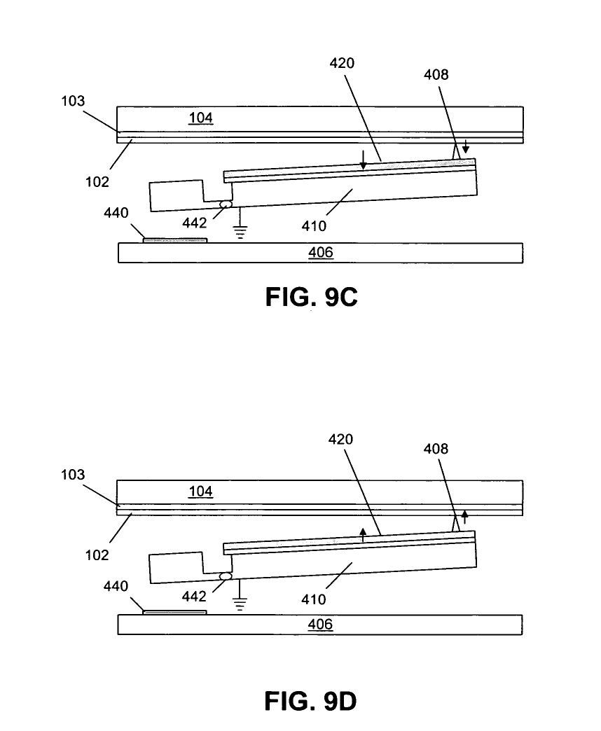

FIGS. 9A-9D illustrates an alternative read mode of the structure of FIGS. 7A-7C. Instead of tuning the oscillating current to the cantilever's resonance, the oscillating current is tuned to the B-plate's resonance. The resonant frequency of the B-plate 420 is determined by the suspended electrode 421 dimension, thickness, and residual stress. The B-plate 420 can be fabricated to specific resonant frequency by proper cantilever frame support and electrode anchor. The read mode of FIGS. 9A-9D does not require resonance of the cantilever 410 and reduces dependence on cantilever 410 structure. As a result, the cantilever 410 can be optimized for vertical actuation. FIGS. 9A and 9B illustrate the resonant mode shapes for the cross-sectional views of FIG. 7B. FIGS. 9C and 9D illustrate the resonant mode shapes for the cross-sectional views of FIG. 7C.

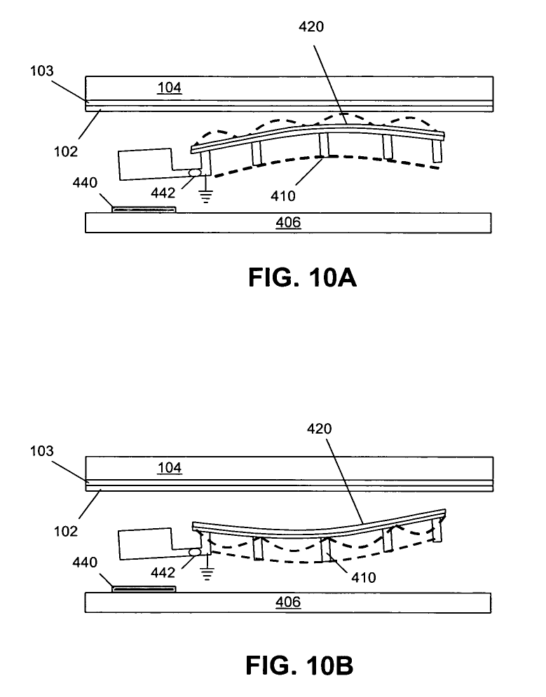

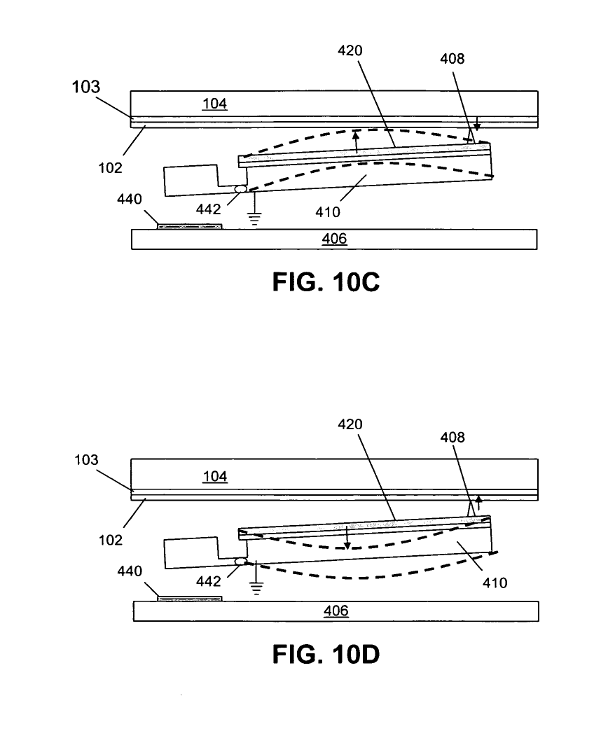

FIGS. 10A-10D illustrate a still further read mode of the structure of FIGS. 7A-7C. The cantilever 410 can have a geometry such that a resonance frequency of the suspended electrodes 421 of the B-plate 420 is a multiple of the resonance frequency of the cantilever 410. The oscillating current is tuned to a common resonance frequency. The modulating capacitance can be further increased by the modified vibration amplitude of the jointly resonating B-plate 420 and cantilever 410. FIGS. 10A and 10B illustrate the resonant mode shapes for the cross-sectional views of FIG. 7B. FIGS. 10C and 10D illustrate the resonant mode shapes for the cross-sectional views of FIG. 7C.

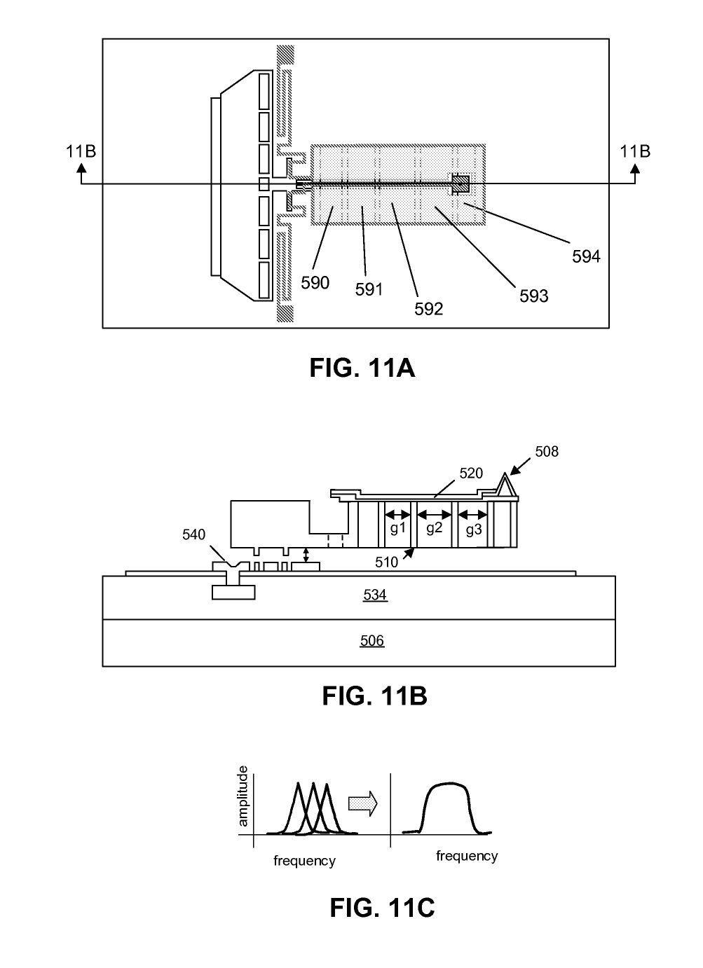

Due to process variation, a cantilever and/or B-plate may have different resonant frequencies from wafer-to-wafer. Sensor circuitry may need to be tunable to a desired frequency, which can potentially affect integration and cost. Referring to FIGS. 11A and 11B, a still further embodiment of a cantilever 510 and B-plate structure 520 is shown for use with embodiments of phase detectors and methods of measuring ferroelectric polarization in accordance with the present invention. A proximal end of the cantilever 510 is suspended over a actuation electrode 540, while a tip 508 extends from a distal end of the cantilever 510. The cantilever 510 comprises a cantilever frame having air gaps of varying dimension (g1, g2, g3, may be 17 um, 21 um, 27 um, for example). As a result, the B-plate 520 comprises a plurality of suspended electrodes 590-594 with varying dimensions. Because the suspended electrodes 590-594 have varying dimensions, the suspended electrodes 590-594 have offsets of resonant frequencies. Although the resonant amplitude may be reduced due to divided electrodes at individual resonant frequencies, the separation of resonant frequencies broadens the net frequency response of the cantilever/B-plate structure. As a result, a frequency of the signal oscillator for generating an oscillating current to cause cantilever/B-plate structure vibration need not be tuned to a precise frequency, but rather a frequency within a range. A simplified exemplary frequency diagram is shown in FIG. 11C, illustrating a frequency of three different suspended electrodes can overlap to represent a range of useful frequency. Embodiments of cantilevers and B-plates having geometries that are dissimilar can provide performance specification that are more forgiving of process variation, improving flexibility in design of electronics and fabrication techniques.

The foregoing description of the present invention has been presented for purposes of illustration and description. It is not intended to be exhaustive or to limit the invention to the precise forms disclosed. Many modifications and variations will be apparent to practitioners skilled in this art. The embodiments were chosen and described in order to best explain the principles of the invention and its practical application, thereby enabling others skilled in the art to understand the invention for various embodiments and with various modifications as are suited to the particular use contemplated. It is intended that the scope of the invention be defined by the following claims and their equivalents.

1. An information storage device comprising:
a ferroelectric media;
a cantilever including:
a tip extending from the cantilever toward the ferroelectric media;
a capacitive sensor formed over the cantilever;
wherein the tip applies a probe voltage to the ferroelectric media;
wherein the capacitive sensor vibrates according to a response of the ferroelectric media to the probe voltage; and
circuitry that can determine a polarization of the ferroelectric media based on the vibration of the capacitive sensor.

2. The information storage device of claim 1, wherein the probe voltage is an alternating current having a frequency matched to a resonant frequency of one or both of the capacitive sensor and the cantilever.

3. The information storage device of claim 1, wherein the circuitry includes an amplitude modulation demodulator.

4. The information storage device of claim 1, wherein the ferroelectric media includes one or more of strontium ruthenate, strontium titanate, and lead zirconate titanate.

5. The information storage device of claim 1, wherein the cantilever includes a frame having a plurality of air gaps and the capacitive sensor is suspended over the air gaps.

6. The information storage device of claim 5, wherein the probe voltage is an alternating current having a frequency matched to a resonant frequency of a portion of the capacitive sensor suspended over an air gap.

7. The information storage device of claim 5, wherein the plurality of air gaps have different dimensions.

8. The information storage device of claim 7, wherein the probe voltage is an alternating current having a frequency matched to a resonant frequency of a portion of the capacitive sensor suspended over at least one of the air gaps.

9. The information storage device of claim 1, wherein the cantilever is pivotably connected with a tip die by a torsion beam; and further comprising an actuation electrode formed on the tip die to apply an electrostatic force to the cantilever.

10. The information storage device of claim 1 further comprising one or more tuning slots including a geometry based on a result of one or more preceding fabrication steps.

11. A method of reading information from a ferroelectric media using a tip extending from a cantilever having a capacitive sensor formed over the cantilever comprising:
positioning at least one of the tip and the ferroelectric media relative to the other;
applying a probe voltage to the tip to communicate the probe voltage to the ferroelectric media;
applying a signal voltage to the capacitive sensor;
allowing the capacitive sensor to vibrate in response to vibration of the tip associated with expansion and contraction of the ferroelectric media; and
determining the polarization of the ferroelectric media based on the vibration of the capacitive sensor.

12. The method of claim 11, wherein determining the polarization includes extracting a signal that modulates the signal voltage.

13. The method of claim 11, wherein applying a probe voltage includes applying a probe voltage having a frequency matched to a resonant frequency of one or both of the cantilever and the capacitive sensor.

14. The method of claim 12, wherein extracting a signal includes directing the modulated signal voltage to an amplitude modulation (AM) demodulator.

15. The method of claim 11, further comprising urging at least one of the ferroelectric media and the cantilever relative to the other.

16. The method of claim 15, wherein at least one of the ferroelectric media and the cantilever is urged relative to the other at a rate substantially defined by a frequency of the probe voltage.

17. An information storage device comprising:
a tip die;
a cantilever including:
a frame extending from a proximal end to a distal end and pivotably connected with the tip die by a torsion beam;
a tip extending from the distal end;
a capacitive sensor formed over the frame so that one or more sensor electrodes are defined by the frame;
a ferroelectric media accessible to the tip;
an actuation electrode formed on the tip die to apply an electrostatic force to the cantilever to urge the tip toward the ferroelectric media;
wherein the tip applies a probe voltage to the ferroelectric media;
wherein the sensor electrode vibrates according to a response of the ferroelectric media to the probe voltage; and
circuitry that can determine a polarization of the ferroelectric media based on the vibration of the sensor electrode.

18. The information storage device of claim 17, wherein the probe voltage is an alternating current having a frequency matched to a resonant frequency of one or both of the sensor electrode and the frame.

19. The information storage device of claim 17 wherein the circuitry includes an amplitude modulation demodulator.

20. The information storage device of claim 17, wherein the ferroelectric media includes one or more of strontium ruthenate, strontium titanate, and lead zirconate titanate.

21. The information storage device of claim 17, wherein the frame includes a plurality of air gaps having different dimensions.

22. The information storage device of claim 21 wherein the probe voltage is an alternating current having a frequency matched to a resonant frequency of a sensor electrode suspended over at least one of the air gaps.

23. The information storage device of claim 17, further comprising one or more tuning slots including a geometry based on a result of one or more preceding fabrication steps.
